(19) United States
(12) Patent Application Publication
(10) Pub. No.: US 2005/0156287 A1
(43) Pub. Date: Jul. 21, 2005

(54) Organic polymer film, method for producing the same and semiconductor device using the same

(76) Inventors: Akio Takahashi, Tokyo (JP); Yuichi Satsu, Hitachi (JP); Harukazu Nakai, Kanazawa (JP); Yoshiko Nakai, Kanazawa (JP); Igor Yefimovich Kardash, Moscow (RU); Andrei Vladimirovich Pebalk, Moscow (RU); Sergei Nicolaevich Chvalun, Moscow (RU); Kearen Andranikovich Mailyan, Moscow (RU)

Correspondence Address: Crowell & Moring,, 1001 Pennsylvania Avenue, Washington, DC, 20004-2595, US

(21) Appl. No.: 10/484,893

(22) PCT Filed: Jul. 22, 2002
(86) PCT No.: PCT/JP02/07388

(30) Foreign Application Priority Data
Jul. 27, 2001 (RU) 2001120907

(51) Int. Cl. H01L 21/302; H01L 23/48

(52) U.S. Cl. 257/642; 438/725; 257/643; 257/759; 438/623; 257/758

(57) ABSTRACT

An organic polymer film of low dielectric constant and high heating resistance which is applicable as insulating layers of semiconductor devices, a method of manufacturing the organic polymer film, and a semiconductor device using the organic polymer film.

This application claims the priority of Russian Patent Application No. 2001120907, filed 27 Jul. 2001 and PCT/JP02/07388, filed 22 Jul. 2002 the disclosure of which is expressly incorporated by reference herein, respectively.

### FIELD OF THE INVENTION

This invention relates to insulating films to be used in electronic and electric fields, manufacturing method thereof, and semiconductor device using thereof.

### BACKGROUND OF THE INVENTION

With the development of high-density integration of semiconductor integrated circuits, the size of features such as wiring lines and space between features has been greatly reduced. As a result, line-to-line parasitic capacitances have become greater and affected the operation speeds of the semiconductor integrated circuits. Various suggestions have been made to solve this problem. One such suggestions is to use a poly-paraxylylene film of a low dielectric constant as the wiring insulating film.

For example, a poly-paraxylylene film is prepared by subliming 2,2-paracyclophane at 120° C., pyrolyzing the resulting product into the intermediate of paraxylylene at 650° C., polymerizing the intermediate at 20° C. in a polymerization tank, and depositing the resulting polymer on a substrate.

FIG. 1 shows an example of a manufacturing method for a semiconductor device which uses poly-paraxylylene as an insulating layer. This method produces a semiconductor device having multiple wiring layers by the processes of forming a first aluminum wiring layer 11 on a semiconductor substrate 10, forming an insulating film 12 of poly-paraxylylene prepared by the above method on the aluminum wiring layer 11 of the semiconductor substrate (Process “a”), forming a silicon oxide layer 13 over the above layer by a chemical vapor-phase growth process (Process “b”), grinding the silicon oxide layer 13 by a chemical machine grinding method and forming via-holes in the layer 12 that are filled with tungsten 14 (Process “c”), forming a second aluminum wiring layer 15 on the ground layer 13 (Process “d”), and repeating these processes (a) to (d).

The above method can provide a substrate having multiple wiring layers, that is, a semiconductor device having semiconductor elements on the substrate.

In production of semiconductor devices, heat-treating processes can be added to the above processes. Such processes include a heat-treating process at about 400° C. during formation of a silicon oxide layer and a tungsten layer and a heat-treating process of 1 hour at 400° C. in an air atmosphere during formation of a resistance layer which is required for production of multiple wiring layers. Therefore, the insulating film material is preferably a material that does not generate degradable gases when heated for one hour at 400° C. in an air atmosphere.

The physical properties of the above paraxylylene film degrade when heat-treated at 400° C. As a result, the above paraxylylene film cannot be used as an insulating film for semiconductor integrated circuits that require downsizing of wires and wire pitches.

Reducing the dielectric constant is desirable for insulating films of semiconductor devices. Insulating materials having specific inductive capacity of 2.5 or less have been desired.

MACROMOLECULES 1999, 32, 7555-7561 discloses an organic polymer film having of a low specific inductive capacity of 2.3 and excellent heat resistance. The film is prepared by subliming 1,1,2,2,9,9,10,10-octafluoro-2,2-cyclophane at 70 to 100° C. at a vacuum pressure, pyrolyzing thereof at 650° C., and depositing the resulting polymer onto a cool substrate. However, a film obtained by pyrolyzation at 650° C. contains many components that become volatile at 250 to 400° C. (Mat. Res. Soc. Symp. Proc., 1997, Vol. 443, 21-33 and Mat. Res. Soc. Symp. Proc., 1997, Vol. 476, 213-218). As a result, these material components cannot be completely removed from the film even when the film is heat-treated at 400° C. after formation. No heat-treatment for formation of a resistance layer in an air atmosphere has been disclosed, although some heat-treatments in a gas atmosphere have been described.

### SUMMARY OF THE INVENTION

An object of this invention is to provide an organic polymer film of low dielectric constant and high heating resistance which is applicable as an insulating layer for semiconductor devices. Additional objects include a manufacturing method for such organic polymer films, and a semiconductor device using such films.

These and other objects and advantages are achieved by an organic polymer film having a specific inductive capacity of 2.5 or less and a weight loss ratio of 0.05% or less by weight after one-hour heating in an air or inactive gas atmosphere at 400° C.

In another embodiment, the invention provides an organic polymer film having a specific inductive capacity of 2.0 to 2.5 or less and a weight loss ratio of 0.05% or less by weight after one-hour heating in an air or inactive gas atmosphere at 400° C.

This invention also provides a method for forming an organic polymer film containing fluorinated poly-paraxylylene prepared by subliming a cyclophane compound containing fluorine atoms, pyrolyzing the product of sublimation into paraxylylene monomer, and polymerizing said paraxylylene monomer.

In another embodiment, an organic polymer film containing fluorinated poly-paraxylylene is prepared by subliming 1,1,2,2,9,9,10,10-octafluoro-2,2-cyclophane as a cyclophane compound containing fluorine atoms in the sublimation zone, pyrolyzing the product of sublimation into paraxylylene monomer in the pyrolysis zone, polymerizing paraxylylene monomer into poly-paraxylylene in the polymerization zone, and depositing the poly-paraxylylene on a substrate.

In this embodiment, an organic polymer film containing fluorinated poly-paraxylylene having a specific inductive capacity of 2.5 or less and a weight loss ratio of 0.05% or less by weight after one-hour heating in an air or inactive gas atmosphere at 400° C. is produced.

This invention also provides a method of manufacturing an organic polymer film comprising subliming a cyclophane compound containing fluorine atoms at 30 to 70° C. under a reduced pressure of 0.001 to 0.1 mmHg, pyrolyzing the product of sublimation into paraxylylene monomer at 680 to 770° C., polymerizing said paraxylylene monomer into fluorinated poly-paraxylylene at −40 to +20° C., and heating said fluorinated poly-paraxylylene to alternately increase the temperature and to maintain the temperature in a stepwise manner, wherein the final increasing of the temperature in the stepwise heating increases the temperature to 390 to 410° C.

The pyrolyzing process thermally decomposes the sublimation vapor into paraxylylene monomer at 700 to 750° C. and the cyclophane compound which contains fluorine atoms is 1,1,2,2,9,9,10,10-octafluoro-2,2-cyclophane.

In an embodiment, the stepwise process of heat-treating fluorinated poly-paraxylylene described above comprises one of the following heat-treating methods:
(i) a first step of heating up to 170 to 220° C. at a maximum rate of 5° C./minute, a second step of heating for at least 10 minutes to maintain the temperature at 170 to 220° C., a third step of heating up to 350 to 390° C. at a maximum rate of 1° C./minute, a fourth step of heating for at least 30 minutes to maintain the temperature at 350 to 380° C., a fifth step of heating up to 390 to 410° C. at a maximum rate of 0.5° C./minute, and a sixth step of heating for at least 30 minutes to maintain the temperature at 390 to 410° C.

(ii) a first step of heating up to 190 to 210° C. at a maximum rate of 5° C./minute, a second step of heating for at least 30 minutes to maintain the temperature at 190 to 210° C., a third step of heating up to 370 to 380° C. at a maximum rate of 1° C./minute, a fourth step of heating for at least 60 minutes to maintain the temperature at 370 to 380° C., a fifth step of heating up to 390 to 410° C. at a maximum rate of 0.5° C./minute, and a sixth step of heating for at least 60 minutes to maintain the temperature at 390 to 410° C.

(iii) a first step of heating up to 170 to 220° C. at a maximum rate of 10° C./minute, a second step of heating for at least 10 minutes to maintain the temperature at 170 to 220° C., a third step of heating up to 350 to 390° C. at a maximum rate of 3° C./minute, a fourth step of heating for at least 15 minutes to maintain the temperature at 350 to 390° C., a fifth step of heating up to 390 to 410° C. at a maximum rate of 1° C./minute, and a sixth step of heating for at least 15 minutes to maintain the temperature at 390 to 410° C.

(iv) a first step of heating up to 190 to 210° C. at a maximum rate of 10° C./minute, a second step of heating for at least 15 minutes to maintain the temperature at 190 to 210° C., a third step of heating up to 370 to 380° C. at a maximum rate of 3° C./minute, a fourth step of heating for at least 30 minutes to maintain the temperature at 370 to 380° C., a fifth step of heating up to 390 to 410° C. at a maximum rate of 1° C./minute, and a sixth step of heating for at least 30 minutes to maintain the temperature at 390 to 410° C.

The heat treatments (i) and (ii) are preferably carried out under a reduced pressure of 0.001 to 0.1 mmHg. The heat treatments (iii) and (iv) are preferably carried out in an air atmosphere.

In another embodiment, the invention also provides a semiconductor device whose semiconductor elements are electrically connected to thin-film wirings formed on an insulating film, wherein said insulating film has a specific inductive capacity of 2.5 or less and a weight loss rate of 0.05% or less by weight after heating one hour at 400° C. in an air or inactive gas atmosphere.

In still another embodiment, the invention provides a semiconductor device comprising a first layer on a main surface at least on one surface of a semiconductor substrate, an insulating film formed on the surface of said first wiring layer, a thin-film resistance layer which is electrically connected to said first wiring layer through conductive holes formed in said insulating film, and a second wiring layer which is electrically connected thereto on said thin film resistance layer, wherein said insulating film has a specific inductive capacity of 2.5 or less and a weight loss rate of 0.05% by weight or less after heating one hour at 400° C. in an air or inactive gas atmosphere.

In an embodiment, said semiconductor substrate is a silicon oxide film, said first and second wiring layers are aluminum wiring layers, and said thin film resistance layer is a Cr/SiO₂ film.

Said organic polymer film preferably contains fluorinated poly-paraxylylene prepared by subliming a cyclophane compound containing fluorine atoms, pyrolyzing the product of sublimation into paraxylylene monomer, and polymerizing said paraxylylene monomer.

Further, the organic polymer film preferably contains fluorinated poly-paraxylylene prepared by subliming 1,1,2,2,9,9,10,10-octafluoro-2,2-cyclophane in a sublimation zone, pyrolyzing the product of sublimation into paraxylylene monomer in a pyrolyzation zone, and polymerizing and depositing said paraxylylene monomer as poly-paraxylylene on a substrate in a polymerization zone.

Furthermore, the organic polymer film preferably is made of fluorinated poly-paraxylylene prepared by the processes of subliming a cyclophane compound containing fluorine atoms at 30 to 70° C. under reduced pressure of 0.001 to 0.1 mmHg, pyrolyzing the product of sublimation into paraxylylene monomer at 680 to 770° C., polymerizing said paraxylylene monomer into fluorinated poly-paraxylylene on a substrate at −40 to +20° C., heating said fluorinated poly-paraxylylene to alternately increase the temperature and to maintain the temperature in a stepwise manner, wherein the final increasing step of the stepwise heating increases the temperature to 390 to 410° C. In an embodiment, said stepwise heat-treating process should preferably contain at least one of the above steps (i) to (iv).

Other objects, advantages and novel features of the present invention will become apparent from the following detailed description of the invention when considered in conjunction with the accompanying drawings.

### BRIEF DESCRIPTION OF THE DRAWINGS

FIG. 1 shows sectional views of manufacturing processes of a semiconductor device in accordance with the present invention.

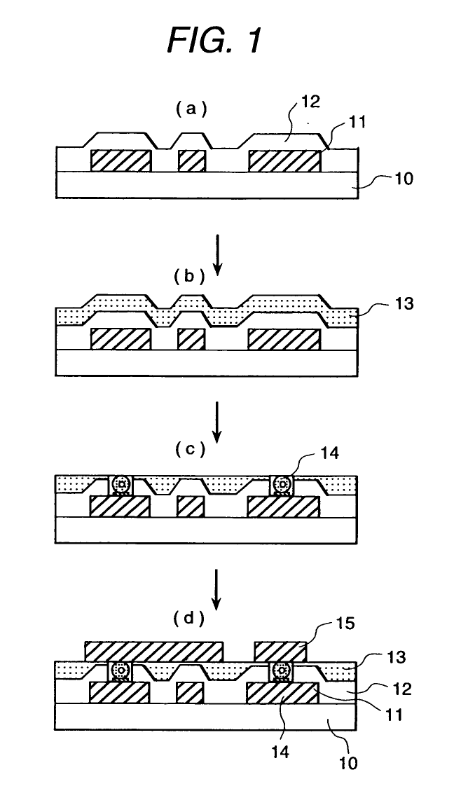

FIG. 2 shows an outlined manufacturing process of an organic polymer film (poly-paraxylylene) in accordance with the present invention.

FIG. 3 shows sectional views of manufacturing processes of a multiplayer wiring substrate in accordance with the present invention.

### DETAILED DESCRIPTION OF THE INVENTION

This invention can provide an organic polymer film having a specific inductive capacity of 2.5 or less and a weight loss rate of 0.05% or less by weight after heating one hour at 400° C. in an air or inactive gas atmosphere. This is provided by selecting a pyrolysis temperature in the range of 680 to 770° C. and more preferably 700 to 750° C. in formation of a polymer film (which is obtained by gas-phase polymerization of a cyclophane compound containing fluorine atoms such as 1,1,2,2,9,9,10,10-octafluoro-2,2-cyclophane or 4,5,7,8,12,13,15,16-octafluoro-2,2-paracyclophane) and by heating the resulting fluorinated poly-paraxylylene alternately to increase the temperature and to maintain the temperature in a stepwise manner, wherein the final increasing step of the stepwise heating increases the temperature to 390 to 410° C.

For efficient pyrolysis of a cyclophane compound containing fluorine atoms such as 1,1,2,2,9,9,10,10-octafluoro-2,2-cyclophane (dimer) into monomer, a pyrolysis temperature of this invention should preferably be in the range of 680 to 770° C. and more preferably 700 to 750° C. If the pyrolysis temperature is below 680° C., the pyrolysis from dimer to monomer is insufficient and consequently, the fluorinated poly-paraxylylene cannot have the expected specific inductive capacity and heat resistance. On the other hand, when the pyrolysis temperature is above 770° C., the resulting monomer is further pyrolyzed in to unwanted by-products that reduce the heat resistance of fluorinated poly-paraxylylene. In other words, the by-products contain a lot of ingredients that are volatile at 250 to 400° C. These by-products cannot be removed even when a formed film is heat-treated at 400° C.

To obtain an organic polymer film having a weight loss ratio of 0.05% by weight after one-hour heating at 400° C., the above polymerization reactions are performed under a reduced pressure of 0.001 to 0.1 mmHg. It is preferable to sublime 1,1,2,2,9,9,10,10-octafluoro-2,2-cyclophane at 30 to 70° C. and polymerize at −40 to +20° C. Further it is preferable to add a process of heating the formed film alternately to increase the temperature and to maintain the temperature in a stepwise manner, wherein the final increasing step of the stepwise heating increases the temperature to 390 to 410° C.

This heat treatment can be done in the presence of air but the stepwise heating condition is dependent upon the atmosphere. The heat-treatment in a vacuum pressure of 0.001 to 0.1 mmHg should preferably comprise a first step of heating up to 170 to 220° C. at a maximum rate of 5° C./minute, a second step of heating for at least 10 minutes to maintain the temperature, a third step of heating up to 350 to 390° C. at a maximum rate of 1° C./minute, a fourth step of heating for at least 30 minutes to maintain the temperature in this range, a fifth step of heating up to 390 to 410° C. at a maximum rate of 0.5° C./minute, and a sixth step of heating for at least 30 minutes at 390 to 41° C. More preferably, the heat-treatment should comprise a first step of heating up to 190 to 210° C. at a maximum rate of 5° C./minute, a second step of heating for at least 30 minutes to maintain the temperature, a third step of heating up to 370 to 380° C. at a maximum rate of 1° C./minute, a fourth step of heating for at least 60 minutes to maintain the temperature in this range, a fifth step of heating up to 390 to 410° C. at a maximum rate of 0.5° C./minute, and a sixth step of heating for at least 60 minutes to maintain the temperature in this range.

In an air atmosphere, the heat-treatment should comprise a first step of heating up to 170 to 220° C. at a maximum rate of 10° C./minute, a second step of heating for at least 10 minutes to maintain the temperature, a third step of heating up to 350 to 390° C. at a maximum rate of 3° C./minute, a fourth step of heating for at least 15 minutes to maintain the temperature in this range, a fifth step of heating up to 390 to 410° C. at a maximum rate of 1° C./minute, and a sixth step of heating for at least 15 minutes to maintain the temperature in this range. Further preferably, the heat-treatment should comprise a first step of heating up to 190 to 210° C. at a maximum rate of 10° C./minute, a second step of heating for at least 15 minutes to maintain the temperature, a third step of heating up to 370 to 380° C. at a maximum rate of 3° C./minute, a fourth step of heating for at least 30 minutes to maintain the temperature in this range, a fifth step of heating up to 390 to 410° C. at a maximum rate of 1° C./minute, and a sixth step of heating for at least 30 minutes to maintain the temperature in this range.

In this invention, we measured the quantity which is lost by heating by Mettler TA-300 (manufactured by Mettler Co.) and processed its data by Solaris operating system (software). The measurement comprises the steps of placing a roll of the film of 10 to 16 mg in a ceramic TG pan, heating it up to 400° C. at a rate of 10° C./minute, keeping it at 400° C. for 1 to 3 hours, and repeated these steps both in the air and nitrogen atmospheres.

This invention will be described in further detail by way of embodiments.

### Embodiment 1

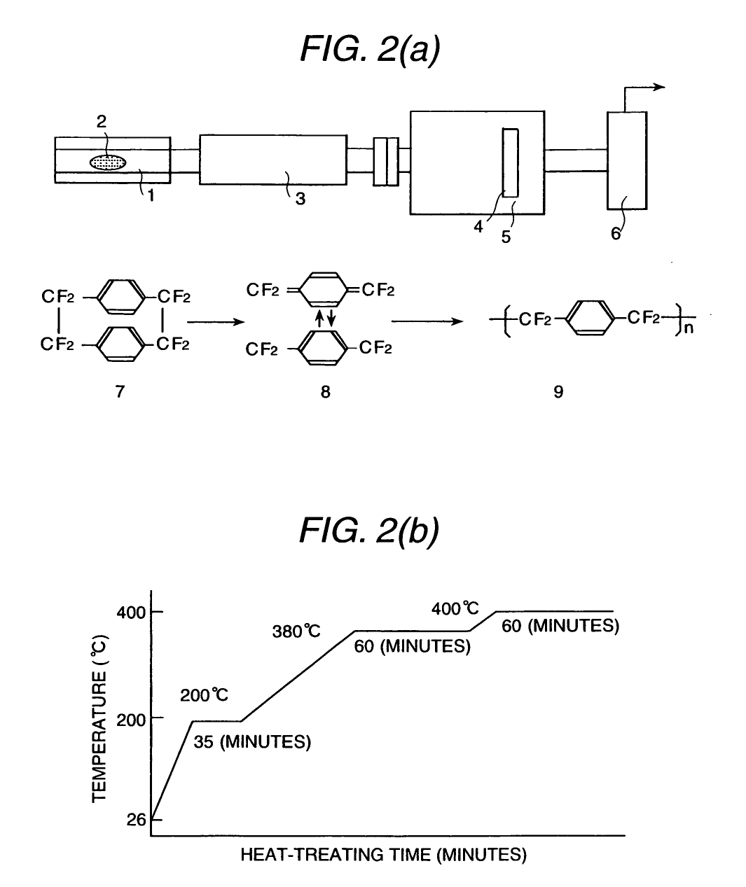

Referring to FIG. 2, embodiments of this invention will be explained below.

We took the steps of putting 1,1,2,2,9,9,10,10-octafluoro-2,2-paracyclophane 7 which is a cyclophane compound containing fluorine atoms in a crucible furnace 2 in the sublimation zone of FIG. 2(a), subliming thereof at 30 to 70° C. into dimer (vapor) under reduced pressure of 0.005 mmHg or higher, heating the crucible furnace 2 at 60° C., sending the dimer 7 to the pyrolyzation zone 3, pyrolyzing thereof into monomer 8 (high-active α,α,α′,α′-tetrafluoro-paraxylylene intermediate) at 750° C., polymerizing and depositing the high-active intermediate 8 on a 50 mm-diameter glass disk 4 which is cooled at −10° C. in the polymerization zone 5. The rate of deposition was 0.27 μm/minute. Here, we obtained a 35 μm-thick organic polymer film containing poly-α,α,α′,α′-tetrafluoro-paraxylylene 9. We further took the steps of returning the pressure of the chamber to the ordinary pressure, putting the film in a glass ampule, evacuating the ampule down to 0.005 mmHg, heat-treating the film in the ampule according to the heat-treatment program of FIG. 2(b) (alternate and stepwise heating to increase the temperature and to keep the temperature) and finally heat-treating thereof at 400° C.

The obtained fluorinated poly-paraxylylene film has a weight loss ratio of 0% after 3-hour heating at 400° C. in the nitrogen atmosphere and a weight loss ratio of 0% after 1-hour heating at 400° C. in the air atmosphere. (The accuracy of measurement of the instrument is 0.05%.)

The final film has a density of 1.62 g/cm³, a specific inductive capacity of 2.20 (at 1 MHz), and a dielectric dissipation factor of 0.001 or less.

### Embodiment 2

We put 1,1,2,2,9,9,10,10-octafluoro-2,2-paracyclophane 7 in a crucible furnace 2 in a chamber under a reduced pressure of 0.005 mmHg or higher. We heated the crucible furnace 2 up to 70° C. to sublime 1,2,2,9,9,10,10-octafluoro-2,2-paracyclophane 7 and moved the sublimation gas from the sublimation zone to the pyrolysis zone. In the pyrolysis zone, the sublimation gas was pyrolyzed into high-active α,α,α′,α′-tetrafluoro-paraxylylene intermediate 8 at 700° C. Then we polymerized and deposited this high reactive intermediate 8 on a 50 mm-diameter glass disk 4 which is kept at −1° C. in the polymerization zone 5. The rate of deposition was 0.26 μm/minute. Here, we obtained a 30 μm-thick organic polymer film containing poly-α,α,α′,α′-tetrafluoro-paraxylylene.

We further took the steps of returning the pressure of the chamber to the ordinary pressure, putting the film in a glass ampule, evacuating the ampule down to 0.005 mmHg, heat-treating the film in the ampule up to 200° C. at a rate of 5° C./minute, keeping thereof at 200° C. for 40 minutes, heating thereof up to 380° C. at a rate of 1° C./minute, keeping thereof at 380° C. for 60 minutes, heating thereof up to 400° C. at a rate of 0.5° C./minute, and keeping thereof at 400° C. for 60 minutes.

The obtained film has a density of 1.62 g/cm³, a specific inductive capacity of 2.20 (at 1 MHz), and a dielectric dissipation factor of 0.001 or less.

The film has a weight loss ratio of 0% after 3-hour heating at 400° C. in the nitrogen atmosphere and a weight loss ratio of 0% after 1-hour heating at 400° C. in the air atmosphere. (The accuracy of measurement of the instrument is 0.05%.).

### Embodiment 3

We put 1,1,2,2,9,9,10,10-octafluoro-2,2-paracyclophane in a crucible furnace in a chamber under a reduced pressure of 0.005 mmHg or higher. We heated the crucible furnace up to 60° C. to sublime 1,2,2,9,9,10,10-octafluoro-2,2-paracyclophane and moved the sublimation gas from the sublimation zone to the pyrolysis zone. In the pyrolysis zone, the sublimation gas was pyrolyzed into high-active α,α,α′,α′-tetrafluoro-paraxylylene intermediate at 730° C. Then we polymerized and deposited this high reactive intermediate on a 100 mm-diameter silicon wafer which is kept at −15° C. in the polymerization zone. The rate of deposition was 0.29 μm/minute. Here, we obtained a 10 μm-thick organic polymer film containing poly-α,α,α′,α′-tetrafluoro-paraxylylene.

We further took the steps of returning the pressure of the chamber to the ordinary pressure, putting the silicon wafer in a vacuum heating furnace, evacuating the chamber down to 0.005 mmHg, heat-treating the silicon wafer up to 200° C. at a rate of 5° C./minute, keeping thereof at 200° C. for 30 minutes, heating thereof up to 380° C. at a rate of 1° C./minute, keeping thereof at 380° C. for 60 minutes, heating thereof up to 400° C. at a rate of 0.5° C./minute, and keeping thereof at 400° C. for 60 minutes.

The obtained film has a specific inductive capacity of 2.20 (at 1 MHz), and a dielectric dissipation factor of 0.001 or less.

The film has a weight loss ratio of 0% after 3-hour heating at 400° C. in the nitrogen atmosphere and a weight loss ratio of 0% after 1-hour heating at 400° C. in the air atmosphere. (The accuracy of measurement of the instrument is 0.05%.)

### Embodiment 4

Referring to FIG. 2, a semiconductor device of this invention will be explained below.

We prepared a semiconductor device having multi-layer wirings by repeating a set of:
Step “a” of forming a first aluminum wiring 11 on a semiconductor substrate 10, and forming an organic polymer layer 12 of poly-α,α,α′,α′-tetrafluoro-paraxylylene on the aluminum wiring 11 in the same preparation method as Embodiment 3,
Step “b” of heating the formed film for 30 minutes at 400° C. under reduced pressure of 0.005 mg, and forming a silicon oxide layer 13 over the above layer by a chemical vapor-phase growth at 400° C.,
Step “c” of grinding the silicon oxide layer 13 by a chemical machine grinding method and forming via-holes in the layer with tungsten 14, and
Step “d” forming a second aluminum wiring 15 thereon.

This organic polymer film of the semiconductor device has a specific inductive capacity of 2.2 and thus enables reduction of the line-to-line parasitic capacitances. Accordingly, this invention can accomplish a semiconductor device of fast signal transmission and high reliability.

### Embodiment 5

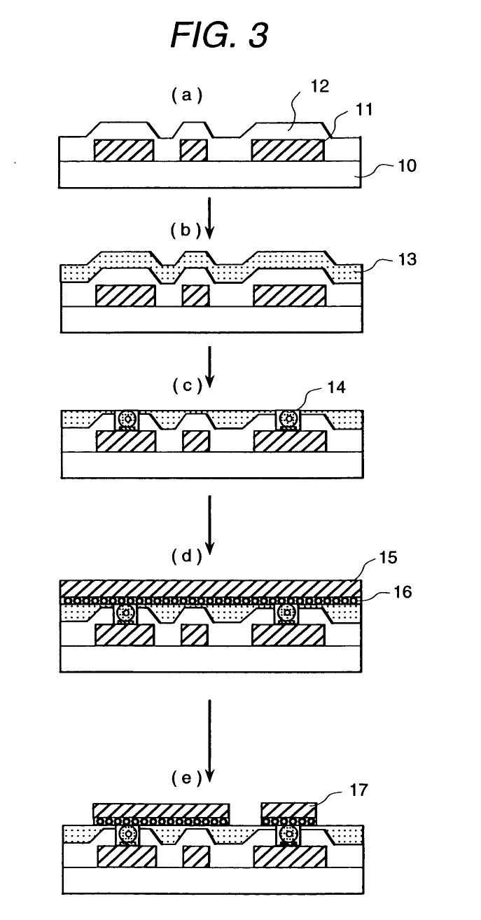

Referring to FIG. 3, a multiple layer wiring substrate of this invention will be explained below.

We prepared a substrate having multiple aluminum wiring layers by repeating a set of:
Step “a” of forming a first aluminum wiring 11 on a semiconductor substrate 10, and forming an organic polymer layer 12 containing poly-α,α,α′,α′-tetrafluoro-paraxylylene on the aluminum wiring 11 in the same preparation method as Embodiment 3,
Step “b” of heating the formed film for 30 minutes at 400° C. under reduced pressure of 0.005 mg, and forming a silicon oxide layer 13 over the above layer by a chemical vapor-phase growth,
Step “c” of grinding the silicon oxide layer 13 by a chemical machine grinding method and forming via-holes in the layer with tungsten 17,
Step “d” of forming a 0.3 μm-thick resistance element film 16 of Cr—SiO₂ (Cr:SiO₂=66:34 (% by weight)) by spattering, heat-treating the film at 400° C. for 2 hours in the air atmosphere to make the resistance stable, and forming a 0.4 μm-thick second aluminum layer 15 on the resistance element film, and
Step “e” of applying a light-sensitive layer (OFPR resist fabricated by Tokyo Ohka Kogyo Co., Ltd.) to the aluminum layer 17, exposing the light-sensitive layer to a resist pattern light, developing the pattern on the aluminum layer with the NMD-3 developer (fabricated by Tokyo Ohka Kogyo Co., Ltd.) (Process 8), etching the pattern-masked aluminum layer with a preset etching solution (phosphoric acid:nitric acid:acetic acid:water=78:2:15:5 by volume), thus forming a second aluminum wiring layer, next etching the resistance element layer with a preset etching solution (aqueous solution of 7.5 mol/l of hydrogen fluoride, 2.4 mol/l of hydrochloric acid, 0.51 mol/l of phosphoric acid, and 3.74 mol/l ammonium fluoride), and thus forming a Cr—SiO₂ wiring layer 16.

The organic polymer film containing poly-α,α,α′,α′-tetrafluoro-paraxylylene of this multiple layer wiring substrate has a specific inductive capacity of 2.2, which enables reduction of the line-to-line parasitic capacity.

In this embodiment, the Cr—SiO₂ wires 16 are formed as thin-film resistance elements for end resistances. The resistance of each Cr—SiO₂ wire is 60±3 ohms, which indicates that the resistance element is highly reliable.

Accordingly, a semiconductor device comprising an organic polymer film containing poly-α,α,α′,α′-tetrafluoro-paraxylylene as an insulating film and a Cr—SiO₂ wiring layer as a thin film resistance element for end resistances can speed up signal transmission and assure high reliability.

### COMPARATIVE EXAMPLE 1

We prepared a 35 μm-thick organic polymer film containing poly-α,α,α′,α′-tetrafluoro-paraxylylene in the same method as Embodiment 1 except that 1,2,2,9,9,10,10-octafluoro-2,2-paracyclophane was pyrolized at 650° C.

We returned the pressure of the chamber to the ordinary pressure, removed the film from the glass disk, put the film in a glass ampule, and evacuated the ampule down to 0.005 mmHg. Then we heat-treated the film in the ampule by heating it up to 400° C. at a rate of 4° C./minute and heating for 60 minutes to keep it at 400° C.

The final film has a density of 1.62 g/cm³, a specific inductive capacity of 2.20 (at 1 MHz), and a dielectric dissipation factor of 0.001 or less.

The film has a weight loss ratio of 0.15% after 3-hour heating at 400° C. in the nitrogen atmosphere and a weight loss ratio of 0.2% after 1-hour heating at 400° C. in the air atmosphere. (The accuracy of measurement of the instrument is 0.05%.)

### COMPARATIVE EXAMPLE 2

We prepared a 35 μm-thick organic polymer film containing poly-α,α,α′,α′-tetrafluoro-paraxylylene in the same method as Embodiment 1 except that dimer 1,2,2,9,9,10,10-octafluoro-2,2-paracyclophane which is the raw material of poly-α,α,α′,α′-tetrafluoro-paraxylylene was pyrolized at 850° C.

We returned the pressure of the chamber to the ordinary pressure, removed the film from the glass disk, put the film in a glass ampule, and evacuated the ampule down to 0.005 mmHg. Then we heat-treated the film in the ampule by heating it up to 400° C. at a rate of 4° C./minute and heating for 60 minutes to keep it at 400° C.

The final film has a density of 1.50 g/cm³, a specific inductive capacity of 2.15 (at 1 MHz), and a dielectric dissipation factor of 0.001 or less.

The film has a weight loss ratio of 0.3% after 3-hour heating at 400° C. in the nitrogen atmosphere and a weight loss ratio of 0.35% after 1-hour heating at 400° C. in the air atmosphere. (The accuracy of measurement of the instrument is 0.05%.)

### COMPARATIVE EXAMPLE 3

We formed a first aluminum wiring layer 11 on a semiconductor 10 and an organic polymer layer 12 containing poly-α,α,α′,α′-tetrafluoro-paraxylylene on this aluminum layer in the same method as Comparative example 2. Then we took processes of heat-treating thereof at 400° C. for 30 minutes under reduced pressure of 0.005 mmHg, forming a silicon oxide layer 13 by a chemical vapor-phase growth at 400° C., grinding the silicon oxide layer 13 by a chemical machine grinding method, forming via-holes with tungsten 14, and forming a second aluminum wiring layer 15.

However, no more processes were carried out because swells and separations due to outgassing were found on the boundary between the organic polymer layer 12 and the silicone oxide layer 13.

The foregoing disclosure has been set forth merely to illustrate the invention and is not intended to be limiting. Since modifications of the disclosed embodiments incorporating the spirit and substance of the invention may occur to persons skilled in the art, the invention should be construed to include everything within the scope of the appended claims and equivalents thereof.

1. An organic polymer film having a specific inductive capacity of 2.5 or less and a weight loss rate of 0.05% or less by weight after heating one hour at 400° C. in an air or inactive gas atmosphere.

2. An organic polymer film having a specific inductive capacity from 2.0 to 2.5 and a weight loss rate of 0.05% or less by weight after heating one hour at 400° C. in an air or inactive gas atmosphere.

3. The organic polymer film of claim 1, wherein said organic polymer film contains fluorinated poly-paraxylylene prepared by subliming a cyclophane compound containing fluorine atoms, pyrolyzing the product of sublimation into paraxylylene monomer, and polymerizing said paraxylylene monomer.

4. The organic polymer film of claim 1, wherein said organic polymer film contains fluorinated poly-paraxylylene prepared by subliming 1,1,2,2,9,9,10,10-octafluoro-2,2-cyclophane in a sublimation zone, pyrolyzing the product of sublimation into paraxylylene monomer in a pyrolyzation zone, and polymerizing and depositing said paraxylylene monomer as poly-paraxylylene on a substrate in a polymerization zone.

5. A method of manufacturing an organic polymer film comprising the processes of:
subliming a cyclophane compound containing fluorine atoms at 30 to 70° C. under a pressure of 0.001 to 0.1 mmHg;
pyrolyzing the product of sublimation into paraxylylene monomer at 680 to 770° C.;
polymerizing said paraxylylene monomer into fluorinated poly-paraxylylene on a substrate at −40 to +20° C. in a polymerization container; and
heating said fluorinated poly-paraxylylene to alternately increase and maintain the temperature in a stepwise manner, wherein the final increasing of said stepwise heating increases the temperature of the poly-paraxylylene to from 390 to 410° C.

6. A method of manufacturing an organic polymer film comprising:
subliming a cyclophane compound containing fluorine atoms;
pyrolyzing the product of sublimation into paraxylylene monomer at 700 to 750° C.;
taking out said paraxylylene monomer and polymerizing said paraxylylene monomer into fluorinated poly-paraxylylene on a substrate at −40 to +20° C. in a polymerization containers; and
heating said fluorinated poly-paraxylylene to alternately increase and maintain the temperature in a stepwise manner, wherein the final increasing of said stepwise heating increases the temperature of the poly-paraxylylene to from 390 to 410° C.

7. A method of manufacturing an organic polymer film comprising the processes of:
subliming a cyclophane compound containing fluorine atoms;
pyrolyzing the product of sublimation into paraxylylene monomer at 700 to 750° C.;
polymerizing said paraxylylene monomer into fluorinated poly-paraxylylene on a substrate at −40 to +20° C. in a polymerization containers; and
heating said fluorinated poly-paraxylylene to alternately increase and maintain the temperature in a stepwise manner, wherein the final increasing of said stepwise heating increases the temperature of the poly-paraxylylene to from 390 to 410° C.

8. The method of manufacturing an organic polymer film of claim 5, wherein said cyclophane compound containing fluorine atoms is 1,1,2,2,9,9,10,10-octafluoro-2,2-paracyclophane.

9. The method of manufacturing an organic polymer film of claim 5, wherein said stepwise heating of fluorinated poly-paraxylylene comprises a first step of heating up to 170 to 220° C. at a maximum rate of 5° C./minute, a second step of heating for at least 10 minutes at 170 to 220° C., a third step of heating up to 350 to 390° C. at a maximum rate of 1° C./minute, a fourth step of heating for at least 30 minutes at 350 to 380° C., a fifth step of heating up to 390 to 410° C. at a maximum rate of 0.5° C./minute, and a sixth step of heating for at least 30 minutes at 390 to 410° C.

10. The method of manufacturing an organic polymer film of claim 5, wherein said stepwise heating of fluorinated poly-paraxylylene comprises a first step of heating up to 190 to 210° C. at a maximum rate of 5° C./minute, a second step of heating for at least 30 minutes at 190 to 210° C., a third step of heating up to 370 to 380° C. at a maximum rate of 1° C./minute, a fourth step of heating for at least 60 minutes at 370 to 380° C., a fifth step of heating up to 390 to 410° C. at a maximum rate of 0.5° C./minute, and a sixth step of heating for at least 60 minutes at 390 to 410° C.

11. The method of manufacturing an organic polymer film of claim 5, wherein fluorinated poly-paraxylylene is heat-treated at a pressure of 0.001 to 0.1 mmHg.

12. The method of manufacturing an organic polymer film of claim 5, wherein said stepwise heating of fluorinated poly-paraxylylene comprises a first step of heating up to 170 to 220° C. at a maximum rate of 10° C./minute, a second step of heating for at least 10 minutes at 170 to 220° C., a third step of heating up to 350 to 390° C. at a maximum rate of 3° C./minute, a fourth step of heating for at least 15 minutes at 350 to 390° C., a fifth step of heating up to 390 to 410° C. at a maximum rate of 1° C./minute, and a sixth step of heating for at least 15 minutes at 390 to 410° C.

13. The method of manufacturing an organic polymer film of claim 5, wherein said stepwise heating of fluorinated poly-paraxylylene comprises a first step of heating up to 190 to 210° C. at a maximum rate of 10° C./minute, a second step of heating for at least 15 minutes at 190 to 210° C., a third step of heating up to 370 to 380° C. at a maximum rate of 3° C./minute, a fourth step of heating for at least 30 minutes at 370 to 380° C., a fifth step of heating up to 390 to 410° C. at a maximum rate of 1° C./minute, and a sixth step of heating for at least 30 minutes at 390 to 410° C.

14. The method of manufacturing an organic polymer film of claim 5 wherein fluorinated poly-paraxylylene is heat-treated in an air atmosphere.

15. A semiconductor device whose semiconductor elements are electrically connected to thin-film wirings formed on an insulating film, wherein said insulating film is an organic polymer film according to claim 1.

16. A semiconductor device comprising:
a first wiring layer at least one surface of a semiconductor substrate;
an insulating film formed on a surface of said first wiring layer;
a thin-film resistance layer which is electrically connected to said first wiring layer through conductive holes formed in said insulating film; and
a second wiring layer electrically connected to said thin film resistance layer, wherein said insulating film is an organic polymer film according to claim 1.

17. The semiconductor device of claim 16, wherein said semiconductor substrate is a silicon oxide film, said first and second wiring layers are aluminum wiring layers, and said thin film resistance layer is a Cr/SiO₂ film.

18. The semiconductor device of claim 15, wherein said semiconductor device uses organic polymer films prepared by a process according to claim 5.

19. The organic polymer film of claim 1, wherein said organic polymer film contains fluorinated poly-paraxylylene prepared by subliming 1,1,2,2,9,9,10,10-octafluoro-2,2-cyclophane, pyrolyzing the product of sublimation into paraxylylene monomer, and polymerizing and depositing said paraxylylene monomer as poly-paraxylylene on a substrate.
